(19) United States
(12) Patent Application Publication
(10) Pub. No.: US 2006/0145302 A1
(43) Pub. Date: Jul. 6, 2006

(54) Coating composition for electronic devices

(76) Inventors: Sang Jin Kim, Seoul (KR); Chang Seok Bae, Suwon-Si (KR); Young Gak Joung, Seoul (KR); Hyun Don Kim, Anyang-Si (KR); Hae Ryong Chung, Suwon-Si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/321,771

(22) Filed: Dec. 28, 2005

(30) Foreign Application Priority Data
Dec. 30, 2004 (KR) 2004-116623
Aug. 1, 2005 (KR) 2005-70188

(51) Int. Cl. H01L 23/58

(52) U.S. Cl. 257/629

(57) ABSTRACT

Disclosed herein is an coating composition for electromagnetic wave shielding, which can effectively solve the problems of electromagnetic interference (EMI) and radio frequency interference (RFI) caused by electromagnetic waves generated from the internal elements of various electronic devices. The composition contains a silver-coated copper particles having fine particle size, so that it can greatly improve the durability of an electroconductive film prepared therefrom. The coating composition comprises a polyurethane binder, a metal particles, a solvent and a rheology control agent, in which the metal particles is either a silver-coated copper particles having an average particle size of 2-20 μm or a mixture of the silver-coated particles and a silver particles having an average particle size of 2-10 μm, and the polyurethane binder is a mixture of at least two kinds of polyurethanes.

### CROSS-REFERENCE TO RELATED APPLICATIONS

This application claims the benefit of Korean Patent Application Nos. 2004-116623, filed on Dec. 30, 2004 and 2005-70188, filed on Aug. 1, 2005, in the Korean Intellectual Property Office, the disclosures of which are incorporated herein in their entirety by this reference thereto.

### BACKGROUND OF THE INVENTION

1. Field of the Invention

The present invention relates to a coating composition for electronic devices, and particularly to a coating composition for electronic devices that shields electromagnetic waves.

2. Description of the Related Technology

Electronic devices such as mobile communication terminals, laptop computers, or medical devices are used close to a human body. According to medical studies, electromagnetic waves emitted from such electronic devices were found to be one of the causes of various ailments such as a headache, a partial vision loss, leukemia, brain tumor, circulatory abnormalities, reproductive function decline, and VDP syndromes. For this reason, concerns have increased about the harmful effects of electromagnetic waves on the human body. Also, as the degree of integration of devices increases with the trend of electronic products toward lightweight, an electromagnetic noise generated from components in electronic products often causes a malfunction of other electronic devices.

Recently, the standards for electromagnetic waves at home or business premises have been established. In addition, strict electromagnetic wave restrictions have been imposed on electronic products, such as computers, wireless telephones, automobiles, medical devices and multimedia players. For example, restrictions on electromagnetic interference (EMI) and radio frequency interference (RFI) have become strict. Therefore, methods of shielding electromagnetic waves from various electronic devices have become even more important.

Examples of methods of shielding electromagnetic waves include plating, vacuum vapor deposition, and spray coating. The plating method has been used for a long time, but it increases production costs, complicates a production process, and causes environmental pollution. The vacuum vapor deposition method has been used only in very limited applications because it incurs high costs and lacks long-term reliability. On the contrary, the spray coating method has been widely used because it is easy to apply without any environmental problems.

The spray coating method typically comprises coating a substrate with a coating solution containing a mixture of an adhesive resin and conductive metal particles. A coating film obtained by a spray coating method is required to have excellent conductivity, substrate adhesion and abrasion resistance. In addition, it needs to show no change in initial physical properties even in various environments. Particularly, a coating film on the inner surface of electronic devices should not change in physical properties under changing conditions encountered during the distribution and use of the electronic devices. When the conductivity or adhesion of a coating film on a substrate becomes poor due to climatic changes, a malfunction of electronic devices can be caused. Therefore, the durability of the coating film is also an essential physical property.

### SUMMARY OF CERTAIN INVENTIVE ASPECTS

An aspect of the invention provides a coating composition for EMI/RFI shielding. The composition comprises a plurality of conductive particles comprising silver-coated copper particles, the silver-coated copper particles having an average particle size of about 2 μm to about 20 μm; and a binder.

In the coating composition described above, the average particle size of the silver-coated copper particles may range from about 8 μm to about 15 μm. The average particle size of the silver-coated copper particles may range from about 14 μm to about 18 μm.

A coating film formed from the coating composition may have an electrical resistance of between about 0.010 ohms/square and about 0.090 ohms/square after subjecting to a condition at 85° C. and 85% relative humidity for 72 hours. A coating film formed from the coating composition may have an adhesion of between 2 B and 5 B when the coating film is tested according to the standard ASTM D3359 after subjecting to a condition at 85 ° C. and 85% relative humidity for 72 hours. A coating film formed from the coating composition may have an electrical resistance of between about 0.010 ohms/square and about 0.070 ohms/square after subjecting to 20 cycles of thermal impacts, wherein each cycle consists of placing the coating film in a condition at −20° C. and then placing the same in another condition at 80° C. A coating film formed from the coating composition may have an adhesion of 4 B or 5 B when the coating film is tested according to the standard ASTM D3359 after subjecting to 20 cycles of thermal impacts, wherein each cycle consists of placing the coating film in a condition at −20° C. and then another condition at 80° C. A coating film formed from the coating composition may have an electrical resistance of between about 0.010 ohms/square and about 0.090 ohms/square after soaking the coating film in a 5% brine water at 25° C. for 72 hours and drying the soaked coating film at 60° C. for 20 minutes. A coating film formed from the coating composition may have an adhesion of between 2 B and 5 B when the coating film is tested according to the standard ASTM D3359 after soaking the coating film in a 5% brine water at 25° C. for 72 hours and drying the soaked coating film at 60° C. for 20 minutes.

In the above coating composition, the plurality of conductive particles may further comprise silver particles. The average particle size of the silver particles may range from about 2 μm to 10 μm. The average particle size of the silver particles may range from about 2 μm to 6 μm. The weight ratio of the silver-coated copper particles to the silver particles may be between about 99:1 and about 30:70. The silver-coated copper particles may be in an amount from about 55 to about 99 weight percent with reference to the total amount of the conductive particles. The conductive particles may be surface-treated with an anti-oxidation agent. The anti-oxidation agent may comprise at least one of oleic acid and stearic acid. The conductive particles may be in an amount from about 10 wt % to about 60 wt % with reference to the total weight of the composition.

In the coating composition, the binder may comprise a polyurethane resin selected from the group consisting of a first polyurethane resin, a second polyurethane resin, and a mixture thereof, wherein the first polyurethane resin may be represented by Formula 1:

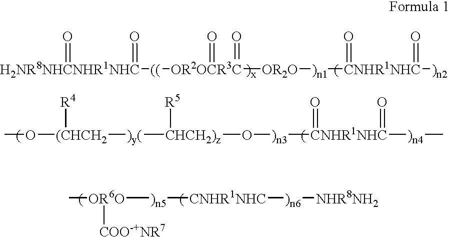

wherein R1 represents an aliphatic hydrocarbon having from about 4 to about 12 carbon atoms or a cyclic aliphatic hydrocarbon having from about 6 to about 15 carbon atoms; wherein R2 represents an aliphatic hydrocarbon having from about 2 to about 12 carbon atoms; wherein R3 represents an aromatic hydrocarbon having from about 6 to about 20 carbon atoms; wherein each of R4 and R5 represents a hydrogen atom or a methyl group; wherein R6 represents an aliphatic hydrocarbon having from about 3 or about 4 carbon atoms; wherein R7 represents a hydrogen atom or an aliphatic hydrocarbon having from 1 to about 9 carbon atoms; wherein R8 represents an aliphatic hydrocarbon having from 1 to about 10 carbon atoms or a cyclic aliphatic hydrocarbon having from about 3 to about 10 carbon atoms; wherein the ratio of n1: n2+n4+n6: n3: n5 is from about 0.2 to about 1.5: from about 1 to about 3: from about 0.01 to about 0.3: from about 0.1 to about 1 and in the ratio, “n2+n4+n6” represents a total number of repeating units containing CNHR¹NHC in the formula 1; and wherein x is an integer from 1 to about 20, and the sum of y and z is an integer from about 5 to about 200. The second polyurethane resin may be also represented by Formula 1 except that R3 in the second polyurethane resin represents an aliphatic hydrocarbon having from about 2 to about 20 carbon atoms. The binder may comprise a mixture of the first polyurethane resin and the second polyurethane resin, and the weight ratio of the first polyurethane resin to the second polyurethane resin may be between about 70:30 and about 20:80. The binder may be in an amount from about 0.01 wt % to about 30 wt % with reference to the total weight of the composition.

The coating composition described above may further comprise a rheology control agent in an amount from about 5wt % to about 20 wt % with reference to the total weight of the composition. The composition may be in the form of a paste. The coating composition may further comprise a solvent, and the solvent may comprise at least one selected from the group consisting of methyl alcohol, ethyl alcohol, isopropyl alcohol, ethyl acetate, methyl pyrrolidone, acetone, methyl cellosolve, ethyl cellosolve and butyl cellosolve. The solvent may be in an amount from about 10 wt % to about 60 wt % with reference to the total weight of the composition.

Another aspect of the invention provides a method of making an electronic device. The method comprises: providing an intermediate product of an electronic device, the intermediate product comprising a surface; applying the coating composition described above onto the surface of the intermediate product; and drying the composition. Drying may comprise heating the surface to a temperature of between about 40° C. and about 70° C. The intermediate product may comprise a housing of an electronic circuit, and the housing may comprise the surface.

Yet another aspect of the invention provides an electronic device made by the method described above.

Yet another aspect of the invention provides an electronic device. The electronic device comprises: a housing for enclosing at least part of an electronic circuit, the housing comprising a surface; a film formed on the surface, the film being coated from the coating composition described above.

Another aspect of the invention provides an electronic device comprising: an electronic circuit; a housing for enclosing at least part of the electronic circuit, the housing comprising a surface; and a film formed on the surface of the housing. The film comprises a plurality of conductive particles comprising silver-coated copper particles, the silver-coated copper particles having an average particle size of about 2 μm to about 20 μm. The surface may comprise an interior surface of the housing. The average particle size of the silver-coated copper particles may range from about 8 μm to about 15 μm. The average particle size of the silver-coated copper particles may range from about 14 μm to about 18 μm. The plurality of conductive particles may further comprise silver particles having an average particle size ranging from about 2 μm to about 10 μm. The weight ratio of the silver-coated copper particles to the silver particles may be between about 99:1 and about 30:70. The weight ratio of the silver-coated copper particles to the silver particles may be between about 99:1 and about 55:45.

### DETAILED DESCRIPTION OF CERTAIN INVENTIVE EMBODIMENTS

Various aspects and features of the invention will become more fully apparent from the following description.

According to one embodiment, a coating composition includes a binder and a plurality of conductive particles comprising first metal particles coated with second metal. In another embodiment, the conductive particles further include second metal particles. The weight ratio of the first metal particles to the second metal particles is between about 99:1 and about 30:70.

In one embodiment, the first metal may be copper and the second metal may be silver. The binder may be a polyurethane resin. The coating composition may further include a rheology control agent and a solvent.

The coating composition is used to shield electromagnetic waves emitted from electronic devices. The composition is applied onto a surface of a housing of various electronic devices to form a coating film thereon. It may also be applicable to various constructional parts for use as an electromagnetic wave shielding material. Each component of the coating composition will now be described below in detail.

Conductive Particles

The coating composition includes a plurality of conductive particles. In one embodiment, the conductive particles may include first metal particles coated with second metal; In another embodiment, the conductive particles may further include second metal particles. In a certain embodiment, the conductive particles may include third metal particles.

In one embodiment, the conductive particles include copper particles coated with silver. The silver-coated copper particles may have about 0.1 wt % to about 20 wt % of silver coating with reference to the total weight of the silver-coated copper particles. The silver-coated copper particles may have an average particle size (D50 value) of about 2-20 μm, which includes, for example, 2, 3, 4, 5, 6, 7, 8, 9, 10, 11, 12, 13, 14, 15, 16, 17, 18, 19, and 20 μm. In certain embodiments, the silver-coated copper particles have an average particle size (D50 value) ranging between two of the foregoing values. In another embodiment, silver-coated copper particles may have an average particle size (D50 value) of about 8-15 μm or about 14-18 μm. Examples of the silver-coated copper particles include, but are not limited to, AgCu-400, AgCu-500 and AgCu-550 (commercially available from Ferro Corp., USA).

In another embodiment, the conductive particles further include silver particles. The silver particles may have an average particle size (D50 value) of about 2 to about 10 μm, which includes, for example, 2, 3, 4, 5, 6, 7, 8, 9, and 10 μm. In certain embodiments, the silver particles have an average particle size (D50 value) ranging between two of the foregoing values. In other embodiments, silver particles may have an average particle size (D50 value) of about 2-4 μm, about 4-6 μm or about 6-10 μm. Examples of the silver particles include, but are not limited to, SF-70A, SF-9ED and SF-9 (Ferro Corp., USA) and SF-162 (HRP Co.).

In one embodiment, the weight ratio of the silver-coated copper particles to the silver particles is between about 99:1 and about 30:70, which includes, for example, 99:1, 98:2, 97:3, 96:4, 95:5, 94:6, 93:7, 92:8, 91:9, 90:10, 89:11, 88:12, 87:13, 86:14, 85:15, 84:16, 83:17, 82:18, 81:19, 80:20, 79:21, 78:22, 77:23, 76:24, 75:25, 74:26, 73:27, 72:28, 71:29, 70:30, 69:31, 68:32, 67:33, 66:34, 65:35, 64:36, 63:37, 62:38, 61:39, 60:40, 59:41, 58:42, 57:43, 56:44, 55:45, 54:46, 53:47, 52:48, 51:49, 50:50, 49:51, 48:52, 47:53, 46:54, 45:55, 44:56, 43:57, 42:58, 41:59, 40:60, 39:61, 38:62, 37:63, 36:64, 35:65, 34:66, 33:67, 32:68, 31:69, and 30:70. In certain embodiments, the ratio ranges between two of the foregoing values. In another embodiment, the weight ratio is between about 99:1 and about 55:45.

In one embodiment, the conductive particles in the coating composition may be surface-treated with a C₄-C₂₂ fatty acid. Such surface treatment is advantageous in that the metal particles can be free from oxidation and have an increased affinity for a binder resin. Examples of the fatty acids include, but are not limited to, oleic acid and stearic acid.

In one embodiment, the conductive particles are in an amount of about 10 wt % to about 60 wt % with reference to the total weight of the coating composition. In other embodiments, the coating composition may include the conductive particles in an amount from about 15 wt % to about 55 wt %, optionally from about 20 wt % to about 50 wt % with reference to the total weight of the coating composition.

Binder

The coating composition may also include a binder. In one embodiment, the binder may be a polyurethane resin. In other embodiments, the binder may include a mixture of at least two kinds of polyurethane resins. The use of the at least two polyurethane resins provides improved adhesiveness and salt-water resistance.

In one embodiment, the binder may include a first polyurethane resin and a second polyurethane resin. The first polyurethane resin may be represented by Formula 1 below:

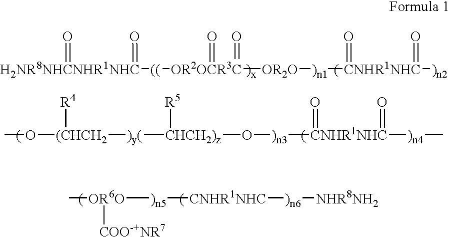

In the formula, R¹ represents an aliphatic hydrocarbon having from about 4 to about 12 carbon atoms or a cyclic aliphatic hydrocarbon having from about 6 to about 15 carbon atoms. R² represents an aliphatic hydrocarbon having from about 2 to about 12 carbon atoms. R³ represents an aromatic hydrocarbon having from about 6 to about 20 carbon atoms. Each of R⁴ and R⁵ represents a hydrogen atom or a methyl group. R⁶ represents an aliphatic hydrocarbon having from about 3 or about 4 carbon atoms. R⁷ represents a hydrogen atom or an aliphatic hydrocarbon having from 1 to about 9 carbon atoms. R⁸ represents an aliphatic hydrocarbon having from 1 to about 10 carbon atoms or a cyclic aliphatic hydrocarbon having from about 3 to about 10 carbon atoms. The ratio of n1: n2+n4+n6: n3: n5 is from about 0.2 to about 1.5: from about 1 to about 3: from about 0.01 to about 0.3: from about 0.1 to about 1. In the above ratio, “n2+n4+n6” represents a total number of repeating units containing CNHR¹NHC in the formula 1. In the formula 1, x is an integer from 1 to about 20. The sum of y and z is an integer from about 5 to about 200. The second polyurethane resin may be represented by the above Formula 1 except that R³ represents an aliphatic hydrocarbon having from 2 to about 20 carbon atoms.

The first polyurethane resin may be obtained by reacting isocyanate with a polyester-based polyol having an aromatic structure. The second polyurethane resin may be obtained by reacting isocyanate with a polyester-based polyol having an aliphatic structure.

The first polyurethane resin may include, but are not limited to, PS-3 and PS-6 (commercially available from Ortec Inc.) and SANCURE 1591 (Noveon Inc.). The second polyurethane resin may include, but are not limited to, SANCURE 12954 and SANCURE 2715 (Noveon Inc.) and Neorez-R-9679 (Avecia Inc.). In one embodiment of the composition, the weight ratio of the first polyurethane resin to the second polyurethane resin ranges from about 70:30 (w/w) to about 20:80 (w/w).

In one embodiment, the coating composition may include the polyurethane binder in an amount of about 0.5 wt % to about 30 wt % with reference to the total weight of the coating composition. In other embodiments, the coating composition may include the polyurethane binder in an amount from about 5 wt % to about 25 wt %, optionally from about 10 wt % to about 20 wt % with reference to the total weight of the coating composition.

Solvent

In one embodiment, the coating composition may include a solvent. The solvent may be at least one selected from methyl alcohol, ethyl alcohol, isopropyl alcohol, ethyl acetate, methyl pyrrolidone, acetone, methyl cellosolve, ethyl cellosolve and butyl cellosolve.

In one embodiment, the coating composition may include the solvent in an amount of about 10 wt % to about 60 wt % with reference to the total weight of the coating composition. In other embodiments, the coating composition may include the solvent in an amount from about 15 wt % to about 50 wt %, optionally from about 20 wt % to about 40 wt % with reference to the total weight of the coating composition.

Rheology Control Agent

In one embodiment, the coating composition may include a rheology control agent to make the composition a paste form. The coating composition may be better in a paste form than in a powder form. The paste form prevents the conductive particles and binders in the composition from aggregating with each other. The rheology control agent may be an acrylic polymer. Examples of the rheology control agent may include, but are not limited to, EX-2 and C676 (commercially available from Carbopol) and Rheolate 5000 (Rhenox).

In one embodiment, the coating composition may include the rheology control agent in an amount of about 5 wt % to about 20 wt % with reference to the total weight of the coating composition. In other embodiments, the coating composition may include the rheology control agent in an amount from about 8 wt % to about 18 wt %, optionally from about 10 wt % to about 15 wt % with reference to the total weight of the coating composition.

Other Additives

Additionally, the coating composition may include certain additives including a leveling agent and a dispersing agent. In one embodiment, such additives may be in an amount of about 0.1 wt % to about 10 wt % with reference to the total weight of the coating composition. In other embodiments, the coating composition may include the additives in an amount from about 0.2 wt % to about 5 wt %, optionally from about 0.5 wt % to about 3 wt % with reference to the total weight of the coating composition.

Preparation of the Coating Composition

In one embodiment, the coating composition may be prepared as follows. First, a paste containing the rheology control agent (Carbopol EZ-2) is prepared. A container is loaded with 950 g of ethanol. Then, 20 g of Carbopol EZ-2 is added to the ethanol while stirring at 700 rpm with a high-speed stirrer. Subsequently, the mixture is stirred at 800 rpm for 30 minutes. The solution is then neutralized with 30 g of a neutralizing agent such as Ethomeen® C-25 commercially available form Akzo. After adding the neutralizing agent, the mixture is stirred at 1,000 rpm for 1 hour. The method described above is presented only by way of example. The paste can be prepared according to any method known to skilled artisans.

Second, the binder is added to the paste containing the rheology control agent. In one embodiment, the first and the second polyurethane resins described above are used as a binder for the coating composition. When added, the polyurethane resins are in the form of dispersion. In one embodiment, the dispersion may include solid polyurethane and a solvent including methyl alcohol, ethyl alcohol, isopropyl alcohol, ethyl acetate, N-methylpyrrolidone, acetone, methyl cellosolve, ethyl cellosolve and butyl cellosolve, and/or water. In one embodiment, the polyurethane dispersions contain solid polyurethane in an amount of about 1 wt % to about 50 wt % with reference to the total weight of the dispersion. When added to the paste, the polyurethane dispersions are added in an amount of about 1 wt % to about 60 wt % with reference to the total weight of the coating composition.

Finally, the conductive particles and other additives may be added to the paste. After the addition, the composition is stirred to control the viscosity. The viscosity is controlled by adjusting the rpm of the stirrer and the stirring time.

Coating Film Formation

A coating film may be formed by applying and drying the coating composition. In one embodiment, the coating composition is applied onto a surface on which the film is to be formed. The surface may include a surface of a housing of an electronic device or an electronic part or component in the electronic device. The surface may be either an inner or outer surface of the housing. In other embodiments, the surface may be a surface of a constructional part.

In one embodiment, the coating composition is sprayed onto the surface. In other embodiments, the composition may be applied by immersing the housing into the composition. Skilled artisans will appreciate the methods of applying the composition onto a given surface.

After applying the coating composition, the composition is subject to heating to vaporize the solvent existing in the coating composition. According to one embodiment, the coating composition is heated to a temperature ranging from about 40° C. to about 70° C. for a period of time ranging from about 5 minutes to about 30 minutes. The drying temperature and time depend on the desired properties of the resulting film. Skilled artisans will appreciate conditions of the drying given the selected coating composition.

Electronic Devices

Another aspect of the invention provides an electronic device comprising a coating film and at least one surface on which the coating film is formed. In one embodiment, the coating film is formed from the coating composition described above. The coating film of the electronic device may include a binder and a plurality of conductive particles comprising copper particles coated with silver. In another embodiment, the conductive particles may further include silver particles. The weight ratio of the silver-coated copper particles to the silver particles may be between about 99:1 to about 30:70. In other embodiments, the weight ratio is between about 90:10 and about 55:45 optionally between about 80:20 and about 60:40. The polymer may be a polyurethane resin.

In one embodiment, the surface on which the coating film is formed may be a surface of an electronic device housing. In other embodiments, the surface may be a surface of a housing of an electronic component in the electronic device. The housing of the electronic device or component may be formed from plastic and/or metallic material. Examples of plastic may include, but are not limited to, polycarbonate, carbonate and acrylo-butadiene-styrene (ABS) resins.

The electronic device may include, but is not limited to consumer electronic products, electronic circuit components, parts of the consumer electronic products, electronic test equipments, etc. The consumer electronic products may include, but are not limited to a mobile phone, a telephone, a television, a computer monitor, a desktop or laptop computer, a hand-held computer, a personal digital assistant (PDA), a vehicle navigation system, a global positioning system (GPS), a microwave, a refrigerator, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi functional peripheral device, etc.

A better understanding of the invention may be obtained in light of the following examples which are set forth to illustrate, but are not to be construed to limit the invention.

### Example 1

A coating composition dispersion equipment, Dispermat D-51580 model (commercially available from VMA GETZMANN GMBH) was loaded with 70 g of an aqueous polyurethane dispersion which is a 2:1(w/w) mixture of SANCURE 12954 (Noveon Inc., USA) and REACTISOL PS-3 (Ortec Inc., USA). Then, 125 g of commercially available silver-coated copper particles (AgCu-550; Ferro Corp., USA) with an average particle size (D50) of 8-15 μm was added. The mixture was stirred at 2000 rpm for 30 minutes. To the mixture, 245 g of ethanol was added. Then, the mixture was stirred at 500 rpm for 10 minutes. To the resulting mixture, 60 g of the Carbopol paste was added. The mixture was stirred at 1000 rpm for 30 minutes to control the viscosity of the solution.

The mixture was diluted with 100 vol % ethanol. The diluted mixture was sprayed on a polycarbonate sample sheet (15 cm width×6 cm length×2 mm thickness). The coated sample sheet was placed and dried in a drying furnace at 60° C. for 15 minutes. A coating film having a thickness of 12.5 μm was formed on the sample sheet. The physical properties of the resulting sample were analyzed. The results are shown in Table 1 below.

### Example 2

Dispermat D-51580 model (VMA GETZMANN GMBH) was loaded with 85 g of an aqueous polyurethane dispersion which is a 2:1 (w/w) mixture of SANCURE 12954 (Noveon Inc., USA) and REACTISOL PS-3 (Ortec Inc., USA). Then, 100 g of a commercially available silver particles (SF-70A; Ferro Corp., USA) having an average particle size (D50) of 2-4 μm and 100 g of a commercially available silver-coated copper particles (AgCu-550; Ferro Co., USA) having an average particle size (D50) of 8-15 μm were added to the mixture. The mixture was stirred at 2000 rpm for 30 minutes. 140 g of ethanol was added to the mixture. Then, the mixture was stirred at 500 rpm for 10 minutes. 75 g of the Carbopol paste was added to the mixture. The mixture was stirred again at 1000 rpm for 30 minutes to control the viscosity of the solution.

The mixture was diluted with 100 vol % ethanol. The diluted mixture was sprayed on a polycarbonate sample sheet (15 cm width×6 cm length x 2 mm thickness). The sprayed sample was dried in a drying furnace at 60° C. for 15 minutes. A coating film having a thickness of 12.5 μm was formed on the sample sheet. The physical properties of the resulting sample were analyzed. The results are shown in Table 1 below.

### Example 3

A coating composition dispersion equipment, Dispermat D-51580 model (commercially available from VMA GETZMANN GMBH) was loaded with 70 g of an aqueous polyurethane dispersion which is a 2:1 (w/w) mixture of SANCURE 12954 (Noveon Inc., USA) and REACTISOL PS-3 (Ortec Inc., USA). Then, 25 g of a commercially available silver particles (SF-70A; Ferro Corp., USA) having an average particle size (D50) of 4-6 μm and 100 g of a commercially available silver-coated copper particles (FX-3; Epsilon Corp, Korea) having an average particle size (D50) of 14-18 μm were added to the mixture. The mixture was stirred at 2000 rpm for 30 minutes. To the mixture, 245 g of ethanol was added. Then, the mixture was stirred at 500 rpm for 10 minutes. To the resulting mixture, 60 g of the Carbopol paste was added. The mixture was stirred at 1000 rpm for 30 minutes to control the viscosity of the solution.

The mixture was diluted with 100 vol % ethanol. The diluted mixture was sprayed on a polycarbonate sample sheet (15 cm width×6 cm length×2 mm thickness). The coated sample sheet was placed and dried in a drying furnace at 60° C. for 15 minutes. A coating film having a thickness of 12.5 μm was formed on the sample sheet. The physical properties of the resulting sample were analyzed. The results are shown in Table 1 below.

### EXAMPLE 4

A coating composition dispersion equipment, Dispermat D-51580 model (commercially available from VMA GETZMANN GMBH) was loaded with 70 g of an aqueous polyurethane dispersion which is a 2:1 (w/w) mixture of SANCURE 12954 (Noveon Inc., USA) and REACTISOL PS-3 (Ortec Inc., USA). Then, 50 g of a commercially available silver particles (SF-7A; Ferro Corp., USA) having an average particle size (D50) of 6-10 μm and 75 g of a commercially available silver-coated copper particles (AgCu-550; Ferro Co., USA) having an average particle size (D50) of 8-15 μm were added to the mixture. The mixture was stirred at 2000 rpm for 30 minutes. To the mixture, 245 g of ethanol was added. Then, the mixture was stirred at 500 rpm for 10 minutes. To the resulting mixture, 60 g of the Carbopol paste was added. The mixture was stirred at 1000 rpm for 30 minutes to control the viscosity of the solution.

The mixture was diluted with 100 vol % ethanol. The diluted mixture was sprayed on a polycarbonate sample sheet (15 cm width×6 cm length×2 mm thickness). The coated sample sheet was placed and dried in a drying furnace at 60° C. for 15 minutes. A coating film having a thickness of 12.5 μm was formed on the sample sheet. The physical properties of the resulting sample were analyzed. The results are shown in Table 1 below.

### Comparative Example 1

The procedure of Example 1 was repeated except that a commercially available silver-coated copper powder (AgCu-250; Ferro Co., USA) having an average particle size (D50) of 35 μm was used instead of the silver-coated copper particles with an average particle size (D50) of 8-15 μm.

### COMPARATIVE EXAMPLE 2

The procedure of Example 2 was repeated except that 100 g of a commercially available silver particles (SF-70A; Ferro Corp., USA) having an average particle size (D50) of 2-8 μm and 100 g of a commercially available silver-coated copper particles (AgCu-200; Ferro Co., USA) having an average particle size (D50) of 45 μm were used instead of the silver particles and the silver-coated copper particles having an average particle size (D50) of 8-15 μm.

### Comparative Example 3

The procedure of Example 1 was repeated except that SANCURE 12954 (Noveon Inc., USA) was used alone instead of the 2:1 mixture of SANCURE 12954 and REACTISOL PS-3.

### COMPARATIVE EXAMPLE 4

The procedure of Example 1 was repeated except that REACTISOL PS-3 (Ortec Inc., USA) was used alone instead of the 2:1 mixture of SANCURE 12954 and REACTISOL PS-3.

### Comparative Example 5

The procedure of Example 1 was repeated except that SANCURE 12954 (Noveon Inc., USA) was used alone instead of the 2:1 mixture of SANCURE 12954 and REACTISOL PS-3. In addition, a silver-coated copper particles (AgCu-250; Ferro Corp., USA) having an average particle size (D50) of 35 μm was used instead of the silver-coated copper particles with an average particle size (D50) of 8-15 μm.

TABLE 1

| | Resistance | Adhesion |
|---|---|---|
| Example 1 | 0.050 | 5B |
| Example 2 | 0.015 | 5B |
| Example 3 | 0.018 | 4B |
| Example 4 | 0.015 | 5B |
| Comparative Example 1 | 0.050 | 5B |
| Comparative Example 2 | 0.015 | 5B |
| Comparative Example 3 | 0.050 | 2B |
| Comparative Example 4 | 0.050 | 3B |
| Comparative Example 5 | 0.060 | 4B |

Physical Properties of Coating Film

Physical properties of the coating film formed from coating compositions prepared in Examples 1-4 and Comparative Examples 1-4 were analyzed as follows. The initial electrical resistance of the coating films was measured in terms of surface resistance per unit area (Ω□ or ohm/square) using a multimeter. The initial adhesiveness of the coating films was measured by a standard adhesion test method, ASTM D3359.

In addition, to analyze the durability of the coating films, the films were placed under various conditions as described below. To analyze the performance of the coating films at a high temperature and high humidity, the coating films were placed at a temperature of 85° C. and a relative humidity of 85% for 72 hours, and their resistance and adhesion were evaluated. To analyze the performance after a thermal impact, the films were subjected to 20 cycles of thermal impact. Each of the cycle consisted of one hour at −20° C. and one hour at 80° C. Then, the resistance and adhesion of the films were evaluated. To analyze salt-water resistance, the films were soaked in 5% salt water at 25° C. for 72 hours and then were dried at 60° C. for 20 minutes. Then, the resistance and adhesion of the films were evaluated. The test results are shown in Table 2 below.

TABLE 2

| | Initial physical | | Physical properties | | Performance | | | |
|---|---|---|---|---|---|---|---|---|
| | properties | | at high temperature | | against heat | | Salt-water | |
| | (after drying) | | and high humidity | | impact | | resistance | |
| | Resistance | | Resistance | | Resistance | | Resistance | |
| | (Ω/□) | Adhesion | (Ω/□) | Adhesion | (Ω/□) | Adhesion | (Ω/□) | Adhesion |
| Example 1 | 0.050 | 5B | 0.050 | 5B | 0.050 | 5B | 0.050 | 5B |
| Example 2 | 0.015 | 5B | 0.015 | 5B | 0.015 | 5B | 0.015 | 5B |
| Example 3 | 0.016 | 4B | 0.016 | 4B | 0.016 | 4B | 0.018 | 3B |
| Example 4 | 0.018 | 4B | 0.018 | 4B | 0.018 | 4B | 0.020 | 4B |
| Comparative | 0.050 | 5B | 0.200 | 0B | 0.080 | 4B | 0.200 | 0B |
| Example 1 | | | | | | | | |
| Comparative | 0.015 | 5B | 0.100 | 1B | 0.020 | 4B | 0.100 | 1B |
| Example 2 | | | | | | | | |
| Comparative | 0.050 | 2B | 0.200 | 1B | 0.080 | 2B | 0.200 | 1B |
| Example 3 | | | | | | | | |
| Comparative | 0.050 | 3B | 0.200 | 1B | 0.080 | 3B | 0.200 | 1B |
| Example 4 | | | | | | | | |
| Comparative | 0.050 | 4B | 0.300 | 1B | 0.100 | 3B | 0.300 | 1B |
| Example 5 | | | | | | | | |

As shown in Table 2, the coating film prepared from the Comparative Examples showed a resistance increase and an adhesiveness decrease after being subjected to the various test conditions. However, the coating films prepared from the Examples appear to have kept the initial physical properties even after being subjected to the conditions. In addition, the films prepared from coating compositions having a mixture of polyurethane binders (Examples 1-4) showed an excellent adhesion and salt-water resistance compared to the films prepared from coating compositions having only one polyurethane binder (Comparative Examples 3-5).

As described above, the coating films according to embodiments of the invention have excellent electrical conductivity. The coating films therefore can shield electromagnetic waves emitted from various electronic devices. The electromagnetic waves may be of various frequencies ranging from a few MHz to a few GHz. Accordingly, the coating films can prevent electromagnetic interference (EMI) and/or radio frequency interference (RFI) caused by electromagnetic waves. In addition, the coating films show good adhesive strength and are durable even under a high temperature and/or humidity conditions.

Although several embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A coating composition for EMI/RFI shielding, the composition comprising:
a plurality of conductive particles comprising silver-coated copper particles, the silver-coated copper particles having an average particle size of about 2 μm to about 20 μm; and
a binder.

2. The coating composition of claim 1, wherein the average particle size of the silver-coated copper particles ranges from about 8 μm to about 15 μm.

3. The coating composition of claim 1, wherein the average particle size of the silver-coated copper particles ranges from about 14 μm to about 18 μm.

4. The coating composition of claim 1, wherein a coating film formed from the coating composition has an electrical resistance of between about 0.010 ohms/square and about 0.090 ohms/square after subjecting to a condition at 85° C. and 85% relative humidity for 72 hours.

5. The coating composition of claim 1, wherein a coating film formed from the coating composition has an adhesion of between 2 B and 5 B when the coating film is tested according to the standard ASTM D3359 after subjecting to a condition at 85° C. and 85% relative humidity for 72 hours.

6. The coating composition of claim 1, wherein a coating film formed from the coating composition has an electrical resistance of between about 0.010 ohms/square and about 0.070 ohms/square after subjecting to 20 cycles of thermal impacts, wherein each cycle consists of placing the coating film in a condition at −20° C. and then placing the same in another condition at 80° C.

7. The coating composition of claim 1, wherein a coating film formed from the coating composition has an adhesion of 4 B or 5 B when the coating film is tested according to the standard ASTM D3359 after subjecting to 20 cycles of thermal impacts, wherein each cycle consists of placing the coating film in a condition at −20° C. and then another condition at 80° C.

8. The coating composition of claim 1, wherein a coating film formed from the coating composition has an electrical resistance of between about 0.010 ohms/square and about 0.090 ohms/square after soaking the coating film in a 5% brine water at 25° C. for 72 hours and drying the soaked coating film at 60° C. for 20 minutes.

9. The coating composition of claim 1, wherein a coating film formed from the coating composition has an adhesion of between 2 B and 5 B when the coating film is tested according to the standard ASTM D3359 after soaking the coating film in a 5% brine water at 25° C. for 72 hours and drying the soaked coating film at 60° C. for 20 minutes.

10. The coating composition of claim 1, wherein the plurality of conductive particles further comprises silver particles.

11. The coating composition of claim 10, wherein the average particle size of the silver particles ranges from about 2 μm to 10 μm.

12. The coating composition of claim 10, wherein the average particle size of the silver particles ranges from about 2 μm to 6 μm.

13. The coating composition of claim 10, wherein the weight ratio of the silver-coated copper particles to the silver particles is between about 99:1 and about 30:70.

14. The coating composition of claim 10, wherein the silver-coated copper particles is in an amount from about 55 to about 99 weight percent with reference to the total amount of the conductive particles.

15. The coating composition of claim 1, wherein the conductive particles are surface-treated with an anti-oxidation agent.

16. The coating composition of claim 15, wherein the anti-oxidation agent comprises at least one of oleic acid and stearic acid.

17. The coating composition of claim 1, wherein the conductive particles are in an amount from about 10 wt % to about 60 wt % with reference to the total weight of the composition.

18. The coating composition of claim 1, wherein the binder comprises a polyurethane resin selected from the group consisting of a first polyurethane resin, a second polyurethane resin, and a mixture thereof,
wherein the first polyurethane resin is represented by Formula 1: 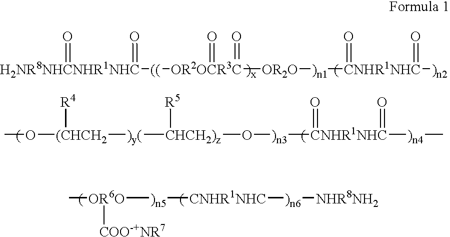
wherein R¹ represents an aliphatic hydrocarbon having from about 4 to about 12 carbon atoms or a cyclic aliphatic hydrocarbon having from about 6 to about 15 carbon atoms;
wherein R² represents an aliphatic hydrocarbon having from about 2 to about 12 carbon atoms;
wherein R³ represents an aromatic hydrocarbon having from about 6 to about 20 carbon atoms;
wherein each of R⁴ and R⁵ represents a hydrogen atom or a methyl group;
wherein R⁶ represents an aliphatic hydrocarbon having from about 3 or about 4 carbon atoms;
wherein R⁷ represents a hydrogen atom or an aliphatic hydrocarbon having from 1 to about 9 carbon atoms;
wherein R⁸ represents an aliphatic hydrocarbon having from 1 to about 10 carbon atoms or a cyclic aliphatic hydrocarbon having from about 3 to about 10 carbon atoms;
wherein the ratio of n1: n2+n4+n6: n3: n5 is from about 0.2 to about 1.5:
from about 1 to about 3: from about 0.01 to about 0.3: from about 0.1 to about 1, and the n2+n4+n6 in the ratio represents a total number of repeating units containing CNHR¹NHC in the Formula 1; and
wherein x is an integer from 1 to about 20, and the sum of y and z is an integer from about 5 to about 200; and
wherein the second polyurethane resin is also represented by Formula 1 except that R³ in the second polyurethane resin represents an aliphatic hydrocarbon having from about 2 to about 20 carbon atoms.

19. The coating composition of claim 18, wherein the binder comprises a mixture of the first polyurethane resin and the second polyurethane resin, and wherein the weight ratio of the first polyurethane resin to the second polyurethane resin is between about 70:30 and about 20:80.

20. The coating composition of claim 1, wherein the binder is in an amount from about 0.01 wt % to about 30 wt % with reference to the total weight of the composition.

21. A method of making an electronic device, the method comprising:
providing an intermediate product of an electronic device, the intermediate product comprising a surface;
applying the coating composition of claim 1 onto the surface of the intermediate product; and
drying the composition.

22. The method of claim 21, wherein the intermediate product comprises a housing of an electronic circuit, and wherein the housing comprises the surface.

23. An electronic device made by the method of claim 21.

24. An electronic device comprising:
a housing for enclosing at least part of an electronic circuit, the housing comprising a surface;
a film formed on the surface, the film being coated from the coating composition of claim 1.

25. An electronic device comprising:
an electronic circuit;
a housing for enclosing at least part of the electronic circuit, the housing comprising a surface; and
a film formed on the surface of the housing, the film comprising a plurality of conductive particles comprising silver-coated copper particles, the silver-coated copper particles having an average particle size of about 2 μm to about 20 μm.

26. The coating composition of claim 25, wherein the surface comprises an interior surface of the housing.
